(19) United States
(12) Patent Application Publication
(10) Pub. No.: US 2026/0365824 A1
(43) Pub. Date: Nov. 19, 2026

(54) LIGHT-ABSORBING COMPOSITION, METHOD FOR MANUFACTURING LIGHT-ABSORBING COMPOSITION, LIGHT-ABSORBING FILM, OPTICAL FILTER, AND METHOD FOR MANUFACTURING OPTICAL FILTER

(71) Applicant: Nippon Sheet Glass Company, Limited, Tokyo (JP)

(72) Inventor: Yuichiro KUBO, Tokyo (JP)

(21) Appl. No.: 19/124,571

(22) PCT Filed: Oct. 18, 2023
(86) PCT No.: PCT/JP2023/037742

§ 371 Date: Apr. 25, 2025

(30) Foreign Application Priority Data
Oct. 27, 2022 (JP) 2022-172216

(51) Int. Cl. C08K 5/07; C08G 71/04; G02B 5/22

(52) U.S. Cl. CPC C08K 5/07; C08G 71/04; G02B 5/223

(57) ABSTRACT

A light-absorbing composition according to the present invention includes: an ultraviolet-absorbing compound having a hydroxy group and a carbonyl group in a molecule; a metal component; polyvinyl butyral; and an isocyanate. At least a portion of the metal component is bonded to an organic oxy group.

### TECHNICAL FIELD

The present invention relates to a light-absorbing composition, a light-absorbing film, and an optical filter.

### BACKGROUND ART

In imaging apparatuses employing a solid-state image sensing device such as a charge coupled device (CCD) or a complementary metal oxide semiconductor (CMOS), any of various optical filters is disposed ahead of the solid-state image sensing device in order to obtain an image with good color reproduction. Solid-state image sensing devices generally have spectral sensitivity over a wider wavelength range than a visual sensitivity region of humans which corresponds to a region of visible light. Thus, a technique is known in which an optical filter blocking a portion of infrared light or ultraviolet light is disposed ahead of a solid-state image sensing device in an imaging apparatus. The technique allows the spectral sensitivity of the solid-state image sensing device to approximate to the visual sensitivity of humans.

It has been common for such an optical filter to block infrared light or ultraviolet light by means of light reflection by a dielectric multilayer film. In recent years, optical filters including a film containing a light absorber have been attracting attention. The transmittance properties of an optical filter including a film containing a light absorber are unlikely to be dependent on the incident angle, and this makes it possible to obtain favorable images with less color change even when light is obliquely incident on the optical filter in imaging apparatuses. Good backlit or nightscape images are easily obtainable using light-absorbing type optical filters not including a light-reflecting film because such optical filters can reduce occurrence of ghosting and flare caused by multiple reflection in a light-reflecting film. Moreover, optical filters including a light-absorber-including film are advantageous also in terms of size reduction and thickness reduction of imaging apparatuses.

Light absorbers including a phosphonic acid and a copper ion are known as light absorbers for such use. For example, Patent Literature 1 describes an optical filter including a light-absorbing layer including a light absorber including a copper ion and a phosphonic acid (phenyl-based phosphonic acid) having a phenyl group or a halogenated phenyl group.

Patent Literature 2 describes an optical filter including a UV-IR absorbing layer capable of absorbing infrared light and ultraviolet light. The UV-IR absorbing layer includes a UV-IR absorber including a phosphonic acid and a copper ion. A UV-IR absorbing composition includes, for example, a phenyl-based phosphonic acid and a phosphonic acid (an alkyl-based phosphonic acid) having an alkyl group or a halogenated alkyl group so that the optical filter will satisfy predetermined optical properties.

Patent Literature 3 describes an ophthalmic device including a violet-light vertical cut-off filter. The violet-light vertical cut-off filter abruptly absorbs light approximately in the wavelength range of 400 nm to 450 nm.

### CITATION LIST

### Patent Literature

Patent Literature 1: WO 2018/088561
Patent Literature 2: JP 6232161 B1
Patent Literature 3: JP 2007-535708 A

### SUMMARY OF INVENTION

### Technical Problem

The techniques described in Patent Literatures 1 and 2 leave room for reconsideration in terms of blocking properties against light in a short wavelength region of 410 nm or less. Additionally, the violet-light vertical cut-off filter described in Patent Literature 3 is thought to have a low transmittance of visible light with a wavelength of 450 nm or more. Furthermore, the techniques according to Patent Literatures 1 to 3 leave room for reconsideration in terms of durability in cleaning of the optical filters or in a manufacturing process of the optical filters.

Therefore, the present invention provides a light-absorbing composition, a light-absorbing film, and an optical filter each having an advantage in reproducing the visual sensitivity of humans, particularly in terms of light absorption properties in a short wavelength region, and each having an advantage in durability in cleaning or a manufacturing process of an optical filter.

### Solution to Problem

The present invention provides a light-absorbing composition including:
an ultraviolet-absorbing compound having a hydroxy group and a carbonyl group in a molecule,
a metal component;
polyvinyl butyral; and
an isocyanate, wherein
at least a portion of the metal component is bonded to an organic oxy group.

The present invention also provides a method for manufacturing the above light-absorbing composition, the method including adding and mixing an ultraviolet-absorbing compound having a hydroxy group and a carbonyl group in a molecule, a compound including a metal component, polyvinyl butyral, and an isocyanate in an organic solvent.

The present invention also provides a light-absorbing film including:
an ultraviolet-absorbing compound having a hydroxy group and a carbonyl group in a molecule;
a metal component; and
a resin including a urethane bond, wherein
at least a portion of the metal component is bonded to an organic oxy group.

The present invention also provides an optical filter including the above light-absorbing film.

The present invention also provides a method for manufacturing an optical filter including the above light-absorbing film, the method including either (i) or (ii) below:
(i) forming the light-absorbing film on an image sensing device or an optical component; or
(ii) forming the light-absorbing film on a substrate, and peeling the light-absorbing film off the substrate.

### Advantageous Effects of Invention

The above light-absorbing composition has an advantage in reproducing the visual sensitivity of humans, particularly in terms of light absorption properties in a short wavelength region, and has an advantage also in durability in cleaning or a manufacturing process of an optical filter. Moreover, the above light-absorbing film and the above optical filter each have an advantage in reproducing the visual sensitivity of humans, particularly in terms of light absorption properties in a short wavelength region. Furthermore, the above light-absorbing film and the above optical filter are less likely to sustain scratches or the like when surfaces thereof are, for example, cleaned or wiped, and thus have an advantage also in durability.

### BRIEF DESCRIPTION OF DRAWINGS

FIG. 1 is a cross-sectional view showing an example of a light-absorbing film according to the present invention.

FIG. 2A is a cross-sectional view showing an example of an optical filter according to the present invention.

FIG. 2B is a cross-sectional view showing an example of an optical filter according to the present invention.

FIG. 3 shows transmission spectra of an optical filter according to Example 1.

FIG. 4 shows transmission spectra of an optical filter according to Example 5.

FIG. 5 shows transmission spectra of an optical filter according to Example 7.

FIG. 6 shows transmission spectra of an optical filter according to Example 9.

FIG. 7 shows transmission spectra of an optical filter according to Example 11.

FIG. 8 shows reflection spectra of an optical filter according to Example 1.

FIG. 9 shows reflection spectra of an optical filter according to Example 5.

FIG. 10 shows reflection spectra of an optical filter according to Example 7.

FIG. 11 shows reflection spectra of an optical filter according to Example 9.

FIG. 12 shows reflection spectra of an optical filter according to Example 11.

FIG. 13 shows a transmission spectrum of a transparent glass substrate.

### DESCRIPTION OF EMBODIMENTS

If an optical filter for an imaging apparatus including a solid-state image sensing device can effectively absorb light in a short wavelength region of 410 nm or less, the optical filter can have a higher value in terms of reproducing the visual sensitivity of humans. As to the optical filter described in Patent Literature 1, a wavelength that lies in the wavelength range of 350 nm to 450 nm and at which a spectral transmittance is 50% is less than 400 nm. As to the optical filter described in Patent Literature 2, a wavelength that lies in the wavelength range of 350 nm to 450 nm and at which a spectral transmittance is 50% is in the wavelength range of about 390 nm to 415 nm. Judging from these facts, it cannot be said that the optical filters described in Patent Literatures 1 and 2 have an advantage in effectively absorbing light in a short wavelength region of 410 nm or less. Although the violet-light vertical cut-off filter described in Patent Literature 3 may be able to effectively absorb light in a short wavelength region of 410 nm or less, the filter is thought to have a low transmittance of visible light with a wavelength of 450 nm or more.

Therefore, the present inventor made intensive studies to create a light-absorbing composition having an advantage in reproducing the visual sensitivity of humans, particularly in terms of effective absorption of light in a short wavelength region of 410 nm or less. Through much trial and error, the present inventor has newly found that a light-absorbing composition including a given ultraviolet-absorbing compound and a given metal component has an advantage in effectively absorbing light in a short wavelength region.

Additionally, the present inventor further studied whether it is possible to impart properties advantageous in terms of durability in cleaning or a manufacturing process of an optical filter to the above light-absorbing composition including the ultraviolet-absorbing compound and the metal component. For example, optical filters are in some cases cleaned by wiping with a wipe or cloth, such as a wiping cloth, a microfiber cloth, or the like dampened with an organic solvent, such as alcohol or acetone. In other cases, during a manufacturing process of an optical filter, a portion including a light-absorbing composition or a solidified product thereof can come into contact with, for example, another member. In view of such circumstances, it is important that the above light-absorbing composition including the ultraviolet-absorbing compound and the metal component has properties advantageous in terms of durability relating to the surface mechanical strength or solvent resistance in cleaning or a manufacturing process of an optical filter, as these properties contribute to enhancing an added value of the light-absorbing composition, a light-absorbing film, or an optical filter. For example, it is important that the light-absorbing composition has properties advantageous in terms of scratch resistance and solvent resistance in cleaning or a manufacturing process of an optical filter.

However, it is not easy to simultaneously impart properties advantageous in terms of durability in cleaning or a manufacturing process of an optical filter and reproduce the visual sensitivity of humans, particularly in terms of effective absorption of light in a short wavelength region of 410 nm or less. This is because when a component to be added to a light-absorbing composition for imparting durability in cleaning or a manufacturing process of an optical filter is selected, careful consideration is necessary to confirm that effective absorption of light in a short wavelength region of 410 nm or less is not impaired by an interaction between the component and, for example, the ultraviolet-absorbing compound. The present inventor made a lot of trial and error from the above perspective. As a result, the present inventor has newly identified addition components for the above light-absorbing composition including the ultraviolet-absorbing compound and the metal component and has completed the present invention, the addition components being capable of imparting properties advantageous in terms of durability in cleaning or a manufacturing process of an optical filter without impairing effective absorption of light in a short wavelength region of 410 nm or less.

Embodiments of the present invention will be described hereinafter. The following description relates to examples of the present invention. The present invention is not limited to the embodiments given below.

The light-absorbing composition according to the present invention includes: an ultraviolet-absorbing compound having a hydroxy group and a carbonyl group in a molecule; a metal component; polyvinyl butyral (PVB); and an isocyanate. The term “isocyanate” as used herein is a compound including —N═C═O (isocyanate group) in its molecule. Additionally, at least a portion of the metal component is bonded to an organic oxy group. Typically, at least a portion of the metal component is bonded to an oxygen atom in the organic oxy group. This makes it likely that a light-absorbing film and an optical filter produced using the light-absorbing composition effectively absorb light in a short wavelength region of 410 nm or less. Moreover, a light-absorbing film or an optical filter can exhibit a high transmittance in the visible region. Therefore, this light-absorbing composition has an advantage in reproducing the visual sensitivity of humans.

Examples of advantageous requirements for ultraviolet-absorbing compounds include: having an appropriate light absorption range and an appropriate light transmission range; having photochemical stability; having a weak photosensitization effect as far as the photosensitization effect exerts no influence on use of the ultraviolet-absorbing compounds; and having thermochemical stability. From the above viewpoints, using a photoexcitation-induced transfer reaction (a hydrogen abstraction reaction in a molecule) of the hydrogen atom in the hydroxy group in a molecule is conceivable as a mechanism of light absorption by the ultraviolet-absorbing compound. Examples of an ultraviolet-absorbing compound that exhibits such a mechanism include compounds such as hydroxybenzophenone, salicylic acid, hydroxyphenyl benzotriazole, hydroxyphenyl triazine, and a substituted acrylonitrile. In hydroxybenzophenone and salicylic acid, a reaction involving transfer of a hydrogen atom between a hydroxy group and a carbonyl group in a molecule relates to absorption of light such as ultraviolet light. On the other hand, in hydroxyphenyl benzotriazole, hydroxyphenyl triazine, and a substituted acrylonitrile, a reaction involving transfer of a hydrogen atom between a hydroxy group and a nitrogen atom in a molecule relates to absorption of light such as ultraviolet light. It is inferred that since these ultraviolet-absorbing compounds have a hydroxy group having an unshared electron pair in a molecule, these ultraviolet-absorbing compounds undergo an interaction, such as partial complexation, with a coexistent metal component or a coexistent hydrogen donor. A comparison is made between a case where an ultraviolet-absorbing compound having a hydroxy group is present alone in a system including an ultraviolet-absorber-including light-absorbing composition, a cured product thereof, or the like and a case where an ultraviolet-absorbing compound having a hydroxy group is coexistent with a metal component or a hydrogen donor in the above system. According to the comparison, optical properties such as light absorption spectra and light transmission spectra of the light-absorbing compositions, the cured products, or the like are different, supporting the above inference. According to the comparison, a phenomenon in which portion of a light absorption band in the wavelength range of 300 nm to 500 nm shifts toward the long wavelength side occurs, in particular, for a light-absorbing film obtained by curing a light-absorbing composition including a metal component and an ultraviolet-absorbing compound having a hydroxy group and a carbonyl group in a molecule and an optical filter including the light-absorbing film. Hence, this light-absorbing film has properties advantageous in effectively and appropriately absorbing light with a wavelength of 410 nm or less. It should be noted that the shifting of the light absorption band toward the long wavelength side can bring to the surface, for example, a phenomenon in which the maximum absorption wavelength in the wavelength range of 300 nm to 500 nm in the transmission spectrum shifts toward the long wavelength side or in which a wavelength (UV cut-off wavelength) that lies in the wavelength range of 300 nm to 500 nm and at which the transmittance is 50% shifts toward the long wavelength side. As can be understood from the above, according to the light-absorbing composition of the present invention, a light-absorbing film being a cured product of the light-absorbing composition, and an optical filter including the light-absorbing film, the inherent absorption properties of the ultraviolet-absorbing compound are adjusted so that light in a short wavelength region can be effectively absorbed. Consequently, the light-absorbing film and the optical filter are likely to have spectral transmittances more appropriate when used with, for example, a solid-state image sensing device.

As described above, the light-absorbing composition includes the PVB and the isocyanate. This makes it likely that the light-absorbing composition has properties advantageous in terms of scratch resistance and solvent resistance in cleaning or a manufacturing process of an optical filter. In particular, the light-absorbing composition including the PVB and the isocyanate has an advantage in terms of improving the scratch resistance and the solvent resistance in cleaning or a manufacturing process of an optical filter. Besides, the light-absorbing composition including the PVB and the isocyanate does not prevent the inherent absorption properties of the ultraviolet-absorbing compound from being adjusted for effective absorption of light in a short wavelength region according to the above mechanism of action.

The PVB is, for example, likely to have high transparency and can have high compatibility with, for example, an organic solvent. Moreover, the PVB has high weather resistance and high light resistance. A light-absorbing film and an optical filter obtained from the light-absorbing composition are also likely to exhibit high weather resistance and high light resistance owing to the PVB included in the light-absorbing composition. Furthermore, the PVB can exhibit properties advantageous as a biner for a functional component, such as the above ultraviolet-absorbing compound.

The PVB is highly adhesive to surfaces of lenses, other optical elements, and substrates, such as transparent dielectric substrates. Therefore, the light-absorbing composition can have properties advantageous also in producing a composite optical element or a composite optical component in which a plurality of members or components are combined.

The PVB is represented, for example, by the following structural formula. In the following structural formula, k is a mole fraction [%] of a vinylbutyral-containing structural unit, m is a mole fraction [%] of a hydroxy-containing structural unit derived from vinylalcohol, and n is a mole fraction [%] of a structural unit derived from vinyl acetate.

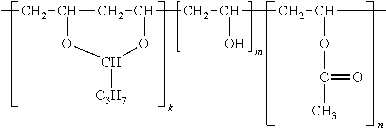

The PVB is obtained by a reaction of butyraldehyde with polyvinyl alcohol (PVA). Because it is impossible to esterify all vinyl groups in the PVA, the PVB partially includes a group having a hydroxy group.

A number average molecular weight of the PVB included in the light-absorbing composition is not limited to a particular value. The number average molecular weight thereof is, for example, 12.0×10⁴ or less. In this case, a film is easily formed from the light-absorbing composition, and a light-absorbing film and an optical filter obtained from the light-absorbing composition tend to have a low haze. The number average molecular weight of the PVB is, for example, 1.0×10⁴ or more. In this case, cure-induced shrinkage of the light-absorbing composition is less likely to be significant, and a light-absorbing film and an optical filter obtained from the light-absorbing composition tend to have a low haze. The number average molecular weight of the PVB may be 1.2×10⁴ or more, or 1.5×10⁴ or more. The number average molecular weight of the PVB may be 11.5×10⁴ or less, or 11.0×10⁴ or less. The number average molecular weight of the PVB can be measured, for example, according to Japanese Industrial Standards (JIS) K 7252-1: 2016.

A degree of butyralization of the PVB is not limited to a particular one. The degree of butyralization thereof is, for example, 60 mol % or more. In this case, the surface hydrophobicity and the toughness of a light-absorbing film or an optical filter obtained from the light-absorbing composition are likely to be adjusted at desired levels. The degree of butyralization is desirably 65 mol % or more. The degree of butyralization is, for example, 90 mol % or less. In this case, a desired amount of hydroxy groups is likely to be present in the PVB. The degree of butyralization is desirably 80 mol % or less. The degree of butyralization of the PVB is, for example, a mole fraction expressed in percentage, the mole fraction being determined by dividing an amount of ethylene groups to which butyral groups are bonded by a total amount of ethylene groups in a main chain of the PVB. The degree of butyralization can be calculated, for example, by measuring a degree of acetylation and a hydroxy group content by a method according to JIS K 6728 (Polyvinyl butyral test method), calculating the mole fraction from the measurement results, and then subtracting the degree of acetylation and the hydroxy group content from 100 mol %.

The hydroxy group content in the PVB is not limited to a particular value. The content is, for example, 10 mol % or more. In this case, as described later, a sufficient amount of hydroxy groups supplied to a reaction with the isocyanate in curing of the light-absorbing composition is likely to be present in the PVB. The hydroxy group content in the PVB is desirably 20 mol % or more. The hydroxy group content in the PVB is, for example, 50 mol % or less. In this case, the PVB is likely to include a desired amount of butyral groups in terms of toughness. The hydroxy group content in the PVB is desirably 40 mol % or less. The hydroxy group content can be calculated, for example, by a method according to JIS K 6728 (Polyvinyl butyral test method).

Examples of the PVB include S-LEC KS-1, S-LEC KS-10, S-LEC BX-L, S-LEC BX-1, S-LEC BL-S, and S-LEC BL-1 manufactured by Sekisui Chemical Co., Ltd. S-LEC is a registered trademark. Other examples of the PVB include Mowital B20H, Mowital B30T, Mowital B30H, and Mowital B45H manufactured by KURARAY CO., LTD. Mowital is a registered trademark. For the light-absorbing composition, one of these PVBs is selected or two or more of these PVBs are selected and mixed.

The isocyanate included in the light-absorbing composition includes, for example, two or more isocyanate groups in a molecule, and each isocyanate group is boned to a carbon atom. As described above, a hydroxy group is included in a molecule of the PVB, and the PVB can cause a crosslinking reaction with the isocyanate. This crosslinking reaction can consume the hydroxy group in the PVB to form a three-dimensional network structure. Specifically, as shown by the following reaction equation, a reaction between the isocyanate group R¹—N═C═O and the hydroxy group R²—OH included in the PVB results in formation of a urethane bond R¹—NH—COO—R², and crosslinking occurs. As a result, the hardness of a surface of a cured product of the light-absorbing composition increases, and mechanical properties and solvent resistance advantageous in terms of the durability in cleaning or a manufacturing process of an optical filter can be achieved.

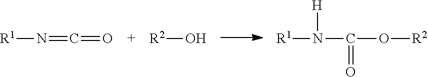

Whether a urethane bond is present or not is confirmed, for example, by obtaining an infrared spectrum of a sample by a method such as Fourier-transform infrared spectroscopy (FT-IR) and analyzing the presence or absence of peaks characteristic to an urethane bond, intensities thereof, etc. in the infrared spectrum. The characteristic peaks are, for example, a peak derived from stretching vibration of N—H in the range of 3450 cm⁻¹ to 3000 cm⁻¹ (e.g., 3290 cm⁻¹), a peak derived from stretching vibration (amide 1) of C═O in the range of 1735 cm⁻¹ to 1691 cm⁻¹ (e.g., 1725 cm⁻¹ and 1705 cm⁻¹), and a peak derived from bending vibration (amide II) of N—H around 1530 cm⁻¹.

The isocyanate included in the light-absorbing composition is not limited to a particular isocyanate. The isocyanate is a compound including an isocyanate group in a molecule. Examples of the isocyanate include tolylene diisocyanate (TDI), diphenylmethane diisocyanate (MDI), hexamethylene diisocyanate (HDI), phenylene diisocyanate, dinaphthalene diisocyanate, isophorone diisocyanate, and xylylene diisocyanate. Other examples of the isocyanate include trimethylene diisocyanate, tetramethylene diisocyanate, pentamethylene diisocyanate, and trimethylhexamethylene diisocyanate. The isocyanate may be an alicyclic polyisocyanate. Examples of the alicyclic polyisocyanate include isophorone diisocyanate, dicyclohexylmethane diisocyanate, 1,3-bis(isocyanatemethyl)cyclohexane, and bis(isocyanatomethyl)norbornane. The isocyanate may be an aromatic-aliphatic polyisocyanate. Examples of the aromatic-aliphatic polyisocyanate include xylylene diisocyanate, tetramethylxylylene diisocyanate, and ω,ω′-diisocyanate-1,4-diethylbenzene.

As described above, at least a portion of the metal component is bonded to the organic oxy group in the light-absorbing composition, and the light-absorbing composition includes a compound including the metal component bonded to the organic oxy group.

The compound including the metal component bonded to the organic oxy group is commonly a compound represented by (R^{k}—O)ₙ-M. The symbol M represents a metal component, such as a metal atom or a metal ion. The group (R^{k}—O)ₙ— represents n organic oxy groups (or collectively referred to as “organic oxy group”; the same applies hereinafter), R^{k} represents an organic group including at least, for example, a carbon atom (C) and a hydrogen atom (H), n represents the number of organic oxy groups bonded or coordinated to a metal component M, and one organic oxy group or a plurality of the organic oxy groups may be bonded or coordinated to the metal component M. The organic oxy group (R^{k}—O)— may include two or more O (oxygen) atoms, and the organic oxy group may be bonded or coordinated to the metal component M via these two or more O (oxygen) atoms. Additionally, the organic groups R^{k} included in the organic oxy groups (R^{k}—O)— bonded or coordinated to the metal component M may be the same or different from each other. A plurality of the organic oxy groups may be bonded to each other without the metal component M interposed therebetween. The organic oxy group is not limited to a particular group as long as the organic oxy group satisfies these requirements. The organic oxy group is, for example, an alkoxy group, such as a methoxy group, an ethoxy group, a propyloxy group, a phenoxy group, or an alkylphenoxy group, or a vinyl group. The organic oxy group may be one whose organic group R^{k} includes an acyl group, an acetyl group, a ketone group, a vinyl group, a propionyl group, an acrylyl group, an acetoxy group, an acryloyl group, an ethylacetate group, an ethyl acetoacetate group, an acetylacetone group, or a partial structure (group) of another ester, ether, or the like. The organic oxy group may be an organic oxy group including one group or two or more groups selected from these. The metal component M may include, for example, at least one selected from the group consisting of metal components, such as metal atoms, ions, and the like of Li, Na, Mg, Ca, Sr, Ba, Ge, Sn, Pb, Al, Ga, In, Tl, Zn, Cd, Cu, Ag, Au, Ni, Pd, Pt, Co, Rh, Ir, Fe, Mn, Cr, Mo, W, V, Nb, Ta, Ti, Zr, and the like.

Disposition of the hydroxy group and the carbonyl group in the ultraviolet-absorbing compound is not limited to particular disposition. In the ultraviolet-absorbing compound, the hydroxy group and the carbonyl group are desirably disposed with one to three atoms in between. In this case, in the ultraviolet-absorbing compound, a hydrogen atom is thought to be likely to transfer between the hydroxy group and the carbonyl group. This is likely to effectively cause the phenomenon in which the light absorption band in the wavelength range of 300 to 500 nm shifts toward the long wavelength side. Consequently, a light-absorbing film obtained by curing the light-absorbing composition is likely to effectively and more reliably absorb light with a wavelength of 410 nm or less.

The ultraviolet-absorbing compound is not limited to a particular compound as long as the ultraviolet-absorbing compound has a hydroxy group and a carbonyl group in a molecule. The ultraviolet-absorbing compound is desirably a compound unlikely to form an aggregate when mixed with the metal component.

The ultraviolet-absorbing compound desirably includes a benzophenone-based compound represented by the following formula (A1). In this case, a light-absorbing film and an optical filter produced using the light-absorbing composition are likely to effectively and more reliably absorb light in a short wavelength region of 410 nm or less.

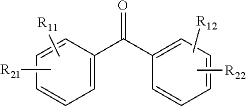

In the formula (A1), at least one of R₁₁, R₁₂, R₂₁, and R₂₂ is a hydroxy group. In the formula (A1), in the case where the R₁₁, the R₁₂, the R₂₁, or the R₂₂ is a functional group other than a hydroxy group, a plurality of the Riis, a plurality of the R₁₂s, a plurality of the R₂₁s, or a plurality of the R₂₂s are optionally present and at least one of the R₁₁, the R₁₂, the R₂₁, and the R₂₂ is optionally absent.

In the case where the R₁₁, the R₁₂, the R₂₁, or the R₂₂ is a functional group other than a hydroxy group, the functional group is, for example, a carboxyl group, an aldehyde group, a halogen atom, an alkyl group having 1 to 12 carbon atoms, an alkyl group that has 1 to 12 carbon atoms and in which one or more hydrogen atoms are substituted by a halogen atom, an alkoxy group having 1 to 12 carbon atoms, or an alkoxy group that has 1 to 12 carbon atoms and in which one or more hydrogen atoms are substituted by a halogen atom.

The ultraviolet-absorbing compound more desirably includes a benzophenone-based compound represented by the following formula (A2). In this case, a light-absorbing film and an optical filter produced using the light-absorbing composition are likely to effectively and more reliably absorb light in a short wavelength region of 410 nm or less.

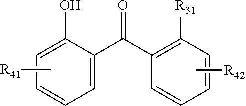

In the formula (A2), R₃₁ is a hydrogen atom, a hydroxy group, a carboxyl group, an aldehyde group, a halogen atom, a halogen-containing group, an alkyl group having 1 to 12 carbon atoms, or an alkoxy group having 1 to 12 carbon atoms. In the formula (A2), R₄₁ and R₄₂ are each optionally a hydroxy group, a carboxyl group, an aldehyde group, a halogen-containing group, an alkyl group having 1 to 12 carbon atoms, an aryl group having 6 to 12 carbon atoms, or an alkoxy group having 1 to 12 carbon atoms, or the R₄₁ and the R₄₂ are optionally absent. In the formula (A2), a plurality of the R₄₁s are optionally present, and a plurality of the R₄₂s are optionally present. The halogen-containing group may be a halogenated alkyl group in which at least one hydrogen atom in an alkyl group is substituted by a halogen atom. The halogen-containing group may be a halogenated aryl group in which at least one hydrogen atom in an aryl group is substituted by a halogen atom. The halogen-containing group may be a halogenated alkoxy group in which at least one hydrogen atom in an alkoxy group is substituted by a halogen atom.

The benzophenone-based compound represented by the formula (A1) or (A2) is not limited to a particular compound. The benzophenone-based compound is, for example, at least one selected from the group consisting of 2,2′-dihydroxy-4,4′-dimethoxybenzophenone, 2,2′,4,4′-tetrahydroxybenzophenone, 2-hydroxy-4-methoxybenzophenone, 2-hydroxy-4-methoxy-4′-chlorobenzophenone, 2-hydroxy-4-n-octoxybenzophenone, 2-hydroxy-4-dodecyloxybenzophenone, 2,4-dihydroxybenzophenone, 2-hydroxy-4-methoxy-2′-carboxybenzophenone, 2,2′-dihydroxy-4-methoxybenzophenone, 2,2′-dihydroxy-4-n-octoxybenzophenone, 2-hydroxy-5-chlorobenzophenone, and 2,4-dibenzoylresorcin.

The ultraviolet-absorbing compound may include a salicylic-acid-based compound represented by the following formula (B). In this case, a light-absorbing film and an optical filter produced using the light-absorbing composition are likely to effectively and more reliably absorb light in a short wavelength region around a wavelength of 410 nm.

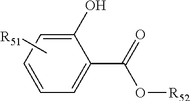

In the formula (B), R₅₁ is optionally a hydroxy group, a carboxy group, a halogen-containing group, an alkyl group having 1 to 12 carbon atoms, an aryl group having 6 to 12 carbon atoms, or an alkoxy group having 1 to 12 carbon atoms. In the formula (B), a plurality of the R₅₁s are optionally present or the R₅₁ is optionally absent. In the formula (B), R₅₂ is a hydrogen atom, an aryl group, or a halogenated aryl group in which one or more hydrogen atoms are substituted by a halogen atom. The halogen-containing group may be a halogenated alkyl group in which at least one hydrogen atom in an alkyl group is substituted by a halogen atom. The halogen-containing group may be a halogenated aryl group in which at least one hydrogen atom in an aryl group is substituted by a halogen atom. The halogen-containing group may be a halogenated alkoxy group in which at least one hydrogen atom in an alkoxy group is substituted by a halogen atom.

The salicylic-acid-based compound represented by the formula (B) is not limited to a particular compound. The salicylic-acid-based compound represented by the formula (B) includes, for example, at least one selected from the group consisting of phenyl salicylate, 4-butylphenyl salicylate, and octylphenyl salicylate.

The metal component is not limited to a particular metal component. The metal component is typically a thermally and chemically stable component not forming an aggregate in the light-absorbing composition and a light-absorbing film produced using the light-absorbing composition. Moreover, the metal component is typically a component capable of interacting with the above-described ultraviolet-absorbing compound.

The metal component includes, for example, at least one selected from the group consisting of Li, Na, Mg, Ca, Sr, Ba, Ge, Sn, Pb, Al, Ga, In, Tl, Zn, Cd, Cu, Ag, Au, Ni, Pd, Pt, Co, Rh, Ir, Fe, Mn, Cr, Mo, W, V, Nb, Ta, Ti, and Zr. In this case, the metal component is likely to interact with the above-described ultraviolet-absorbing compound.

A content CM of the metal component in the light-absorbing composition is not limited to a particular value. The content CM is, for example, 0.005% to 2% on a mass basis. In this case, a light-absorbing film and an optical filter produced using the light-absorbing composition are likely to effectively and more reliably absorb light in a short wavelength region of 410 nm or less. The content CM is desirably 0.01% to 1%, more desirably 0.01% to 0.5%, even more desirably 0.01% to 0.3%.

A content C_{UV} of the ultraviolet-absorbing compound in the light-absorbing composition is not limited to a particular value. The content C_{UV} is, for example, 0.1% to 20% on a mass basis. In this case, a light-absorbing film and an optical filter produced using the light-absorbing composition are likely to effectively and more reliably absorb light in a short wavelength region of 410 nm or less. The content C_{UV} is desirably 0.1% to 15%, more desirably 0.2 to 10%, even more desirably 0.5% to 10%, particularly desirably 1% to 10%.

A ratio R_{UV/M} of an amount of the ultraviolet-absorbing compound to an amount of the metal component in the light-absorbing composition is not limited to a particular value. The ratio R_{UV/M} is, for example, 5 to 300 on a mass basis. In this case, a light-absorbing film and an optical filter produced using the light-absorbing composition are likely to effectively and more reliably absorb light in a short wavelength region of 410 nm or less. The ratio R_{UV/M} is desirably 10 to 300, more desirably 20 to 300, even more desirably 30 to 280.

In the light-absorbing composition, a ratio R_{I/P} of a mass of the isocyanate to a mass of the PVB is not limited to a particular value. The ratio R_{I/P} is, for example, 0.05 to 3.0. In this case, a surface of a cured product of the light-absorbing composition is likely to have higher hardness in consequence of a crosslinking reaction between the PVB and the isocyanate. The ratio R_{I/P} is desirably 0.05 to 3.0, more desirably 0.1 to 0.3, even more desirably 0.2 to 3.0.

In the light-absorbing composition, a ratio R_{I/UV} of the mass of the isocyanate to a mass of the ultraviolet-absorbing compound is not limited to a particular value. The ratio R_{I/UV} is, for example, 0.1 to 3.0. In this case, a surface of a cured product of the light-absorbing composition is likely to have higher hardness, and mechanical properties and solvent resistance advantageous in terms of the durability in cleaning or a manufacturing process of an optical filter are more likely to be achieved. The ratio R_{I/UV} is desirably 0.2 to 3.0, more desirably 0.25 to 3.0.

The method for manufacturing the light-absorbing composition is not limited to a particular method. The light-absorbing composition can be manufactured, for example, by a method including adding and mixing an ultraviolet-absorbing compound having a hydroxy group and a carbonyl group in a molecule, a compound including a metal component, polyvinyl butyral, and an isocyanate in an organic solvent.

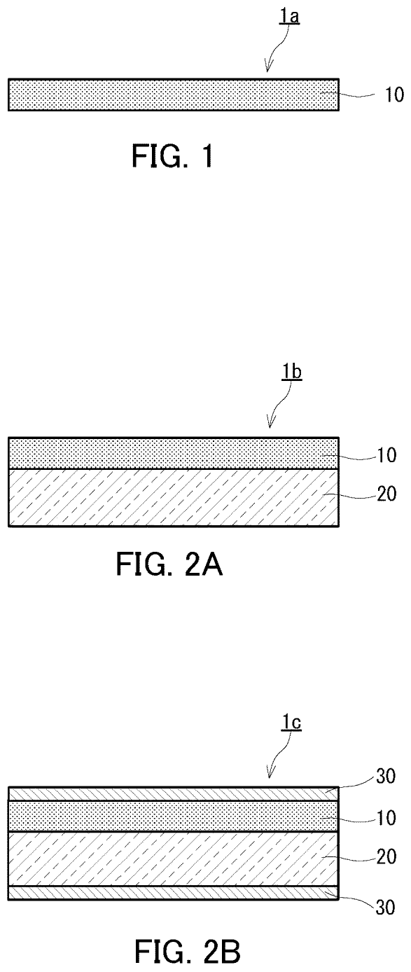

For example, a light-absorbing film 10 shown in FIG. 1 can be provided using the light-absorbing composition. The light-absorbing film 10 can be obtained, for example, by curing the light-absorbing composition. The light-absorbing film 10 includes: an ultraviolet-absorbing compound having a hydroxy group and a carbonyl group in a molecule; a metal component; and a resin including a urethane bond. In the light-absorbing film 10, at least a portion of the metal component is bonded to an organic oxy group. At least a portion of the metal component is bonded to an oxygen atom of the organic oxy group. Because of this, the light-absorbing film 10 is likely to effectively absorb light in a short wavelength region of 410 nm or less. Moreover, since the light-absorbing film 10 includes the resin including the urethane bond, the light-absorbing film 10 is likely to have properties advantageous in terms of improving the durability or the solvent resistance in cleaning of an optical filter.

As described above, at least a portion of the metal component is bonded to the organic oxy group in the light-absorbing film 10, and the light-absorbing film 10 includes a compound including the metal component bonded to the organic oxy group. The compound including the metal component bonded to the organic oxy group is commonly a compound represented by (R^{k}—O)ₙ-M. The symbol M represents a metal component, such as a metal atom or a metal ion. The group (R^{k}—O)ₙ— represents n organic oxy groups (or collectively referred to as “organic oxy group”; the same applies hereinafter), R^{k} represents an organic group including at least, for example, a carbon atom (C) and a hydrogen atom (H), n represents the number of organic oxy groups bonded or coordinated to a metal component M, and one organic oxy group or a plurality of the organic oxy groups may be bonded or coordinated to the metal component M. The organic oxy group (R^{k}—O)— may include two or more O (oxygen) atoms, and the organic oxy group may be bonded or coordinated to the metal component M via these two or more O (oxygen) atoms. Additionally, the organic groups R^{k} bonded or coordinated to the organic oxy groups (R^{k}—O)— may be the same or different from each other. A plurality of the organic oxy groups may be bonded to each other without the metal component M interposed therebetween. The organic oxy group is not limited to a particular group as long as the organic oxy group satisfies these requirements. The organic oxy group is, for example, an alkoxy group, such as a methoxy group, an ethoxy group, a propyloxy group, a phenoxy group, or an alkylphenoxy group, or a vinyl group. The organic oxy group may be one whose organic group R^{k} includes an acyl group, an acetyl group, a ketone group, a vinyl group, a propionyl group, an acrylyl group, an acetoxy group, an acryloyl group, an ethylacetate group, an ethyl acetoacetate group, an acetylacetone group, or a partial structure (group) of another ester, ether, or the like. The organic oxy group may be an organic oxy group including one group or two or more groups selected from these. The metal component M may include, for example, at least one selected from the group consisting of metal components, such as metal atoms, ions, and the like of Li, Na, Mg, Ca, Sr, Ba, Ge, Sn, Pb, Al, Ga, In, Tl, Zn, Cd, Cu, Ag, Au, Ni, Pd, Pt, Co, Rh, Ir, Fe, Mn, Cr, Mo, W, V, Nb, Ta, Ti, Zr, and the like.

In the ultraviolet-absorbing compound of the light-absorbing film 10, the hydroxy group and the carbonyl group are desirably disposed with one to three atoms in between. In this case, it is easy to improve the ability of the light-absorbing film 10 to absorb light in a wavelength region of 410 nm or less.

The ultraviolet-absorbing compound in the light-absorbing film 10 includes, for example, a benzophenone-based compound represented by the above formula (A1). In this case, it is easy to improve the ability of the light-absorbing film 10 to absorb light in a wavelength region of 410 nm or less.

The ultraviolet-absorbing compound in the light-absorbing film 10 desirably includes a benzophenone-based compound represented by the above formula (A2). In this case, it is particularly easy to improve the ability of the light-absorbing film 10 to absorb light in a wavelength region of 410 nm or less

The ultraviolet-absorbing compound in the light-absorbing film 10 may include, for example, a salicylic-acid-based compound represented by the above formula (B). In this case, it is easy to improve the ability of the light-absorbing film 10 to absorb light in a wavelength region of 410 nm or less.

The metal component in the light-absorbing film 10 includes, for example, at least one selected from the group consisting of Li, Na, Mg, Ca, Sr, Ba, Ge, Sn, Pb, Al, Ga, In, Tl, Zn, Cd, Cu, Ag, Au, Ni, Pd, Pt, Co, Rh, Ir, Fe, Mn, Cr, Mo, W, V, Nb, Ta, Ti, and Zr.

In the light-absorbing film 10, a ratio r_{UV/M} of an amount of the ultraviolet-absorbing compound to an amount of the metal component is not limited to a particular value. The ratio r_{UV/M} is, for example, 5 to 300 on a mass basis. In this case, a light-absorbing film and an optical filter produced using the light-absorbing composition are likely to effectively and more reliably absorb light in a short wavelength region of 410 nm or less. The ratio r_{UV/M} is desirably 10 to 300, more desirably 20 to 300, even more desirably 30 to 280.

A transmittance T₄₀₀ of the light-absorbing film 10 is, for example, 5% or less. This is advantageous in terms of reproducing the visual sensitivity of humans. The transmittance T₄₀₀ is a transmittance at a wavelength of 400 nm in a transmission spectrum at an incident angle of 0°. The transmittance T₄₀₀ is desirably 4.5% or less, more desirably 4% or less.

A content of the ultraviolet-absorbing compound in the light-absorbing film 10 is not limited to a particular value. The content is, for example, 0.1% to 90%, desirably 0.5% to 80%, more desirably 2% to 70% on a mass basis.

A content of the metal component in the light-absorbing film 10 is not limited to a particular value. The content is, for example, 0.005% to 5%, desirably 0.01% to 4%, more desirably 0.03% to 3% on a mass basis.

In the light-absorbing film 10, a ratio n/P of a mass of the isocyanate to a mass of the PVB is not limited to a particular value. The ratio n/P is, for example, 0.05 to 3.0, desirably 0.05 to 2.5, more desirably 0.05 to 2.0, even more desirably 1.0 to 2.0.

In the light-absorbing film 10, a ratio r_{I/P} of the mass of the isocyanate to a mass of the ultraviolet-absorbing compound is not limited to a particular value. The ratio r_{I/P} is, for example, 0.1 to 3.0, desirably 0.2 to 2.8, more desirably 0.2 to 2.5.

A thickness of the light-absorbing film 10 is not limited to a particular value. The thickness of the light-absorbing film 10 is, for example, 0.5 μm to 500 μm, and may be 1 μm to 100 μm, or 1 μm to 50 μm.

In manufacturing of the light-absorbing film 10, the method for curing the light-absorbing composition is not limited to a particular method. For example, conditions for curing the light-absorbing composition are adjusted so that a crosslinking reaction between the PVB and the isocyanate included in the light-absorbing composition will occur. This allows the light-absorbing film 10 to include the resin including the urethane bond. For example, the light-absorbing composition may be cured by heating at a given temperature. In this case, the given temperature is, for example, 80 °C or higher, desirably 100 °C or higher, more desirably 120 °C or higher, even more desirably 140 °C to 180 °C. This makes it likely that deterioration of the ultraviolet-absorbing compound is prevented and that the light-absorbing film 10 has properties advantageous in terms of durability in cleaning of an optical filter.

As shown in FIGS. 1 and 2A, for example, optical filters 1a and 1b including the light-absorbing film 10 can be provided. The optical filters 1a and 1b are likely to effectively absorb light in a short wavelength region of 410 nm or less.

In transmission spectra of the optical filters 1a and 1b at an incident angle of 0°, a transmittance T₄₁₀ at a wavelength of 410 nm is, for example, 20% or less, desirably 15% or less, more desirably 10% or less.

A maximum transmittance T^{M}₃₀₀₋₃₈₀ in a wavelength range of 300 nm to 380 nm in the transmission spectra of the optical filters 1a and 1b at an incident angle of 0° is, for example, 3% or less. In this case, the optical filters are likely to effectively absorb light in a short wavelength region of less than 400 nm. The maximum transmittance T^{M}₃₀₀₋₃₈₀ is desirably 2% or less, more desirably 1% or less.

In terms of the transmission spectra of the optical filters 1a and 1b at an incident angle of 0°, a wavelength that lies in a wavelength range of 300 to 520 nm and at which a transmittance is 50% is defined as an ultraviolet cut-off wavelength λ_{UV}. The optical filters 1a and 1b satisfy, for example, a requirement 405 nm≤λ_{UV}≤500 nm. Because of this, the light-absorbing film 10 is likely to effectively absorb light in a short wavelength region around a wavelength of 410 nm, and, in an imaging apparatus used in combination with an image sensing device, light in a region of wavelengths that are hard for humans to perceive is likely to be cut off. The optical filters 1a and 1b desirably satisfy a requirement 405 nm≤λ_{UV}≤490 nm, more desirably a requirement 405 nm≤λ_{UV}≤480 nm.

A minimum transmittance T^{m}₄₀₀₋₅₀₀ in a wavelength range of 480 nm to 600 nm in the transmission spectra of the optical filters 1a and 1b at an incident angle of 0° is, for example, 85% or more. In this case, the optical filters 1a and 1b can appropriately transmit visible light, and can increase, in an imaging apparatus used in combination with an image sensing device, the luminous flux of light coming from a subject and reaching the image sensing device.

The minimum transmittance T^{m}₄₀₀₋₅₀₀ is desirably 86% or more, more desirably 87% or more.

Transmission spectra obtained by allowing light in a wavelength range of 300 nm to 1200 nm to be incident on the optical filters 1a and 1b at an incident angle of 0° may satisfy the following requirements (i-a), (ii-a), (iii-a), (iv-a), (v-a), and (vi-a).
(i-a) The maximum transmittance T^{M}₃₀₀₋₃₈₀ in the wavelength range of 300 nm to 380 nm is 3% or less.
(ii-a) The transmittance T₄₀₀ at a wavelength of 400 nm is 5% or less.
(iii-a) The transmittance T₄₁₀ at a wavelength of 410 nm is 10% or less.
(iv-a) The wavelength λ_{UV} [nm] that lies in the wavelength range of 350 nm to 500 nm and at which the transmittance is 50% is in the range of 405 nm to 490 nm.
(v-a) The minimum transmittance T^{m}₄₈₀₋₆₀₀ in the wavelength range of 480 nm to 600 nm is 85% or more.
(vi-a) A ratio T⁰_{UV+}/T⁰_{UV-} of a transmittance T⁰_{UV+} at a wavelength of (λ_{UV}+10) nm to a transmittance T⁰_{UV-} at a wavelength of (λ_{UV}−10) nm is 1.8 or more.

When satisfying the above requirement (i-a), the optical filters 1a and 1b can exhibit high ultraviolet absorbency.

When satisfying the following requirements (ii-a) and (iii-a) as well as the requirement (i-a), the optical filters 1a and 1b can exhibit a higher ultraviolet absorbency. In particular, the optical filters 1a and 1b can be used in applications where optical filters are required to exhibit higher ultraviolet absorption performance. The transmittance T₄₀₀ is desirably 4% or less.

When satisfying the above requirement (iv-a), the optical filters 1a and 1b can exhibit a high ultraviolet absorbency and a spectrum of light sensed by an image sensing device is likely to partially coincide with a spectrum corresponding to the visual sensitivity of humans. The wavelength λ_{UV} is desirably 420 nm to 490 nm, more desirably 420 nm to 450 nm. In this case, purple fringing is likely to be reduced in images produced using the optical filters 1a and 1b. Purple fringing is a color distortion that produces a near purple color along an edge of a subject. Moreover, in the above case, the transmittance of light belonging to the visible region for humans can be increased and bright images are likely to be obtained.

When the above requirement (v-a) is satisfied, the transmission of light belonging to the visible region for humans is likely to be high and bright images are likely to be obtained. In particular, the transmittance in a wavelength region including a wavelength corresponding to that of the maximum sensitivity in a visual sensitivity curve of humans is likely to be increased, and humans are likely to perceive the brightness more strongly when observing images.

When the above requirement (vi-a) is satisfied, the transmission spectrum abruptly varies in a vicinity of the wavelength λ_{UV} (UV cut-off wavelength); therefore, it is possible for the optical filter to more sharply block ultraviolet invisible to humans and increase the amount of light in the visible region. The ratio T⁰_{UV+}/T⁰_{UV-} is desirably 1.9 or more, more desirably 2.0 or more, even more desirably 2.2 or more, particularly desirably 2.4 or more.

Reflection spectra obtained by allowing light in the wavelength range of 300 nm to 1200 nm to be incident on the optical filters 1a and 1b at an incident angle of 5° may satisfy the following requirements (i-b) and (ii-b). Moreover, reflection spectra obtained by allowing light in the wavelength range of 300 nm to 1200 nm to be incident on the optical filters 1a and 1b at an incident angle of 40° may satisfy the following requirements (iii-b) and (iv-b). Furthermore, reflection spectra obtained by allowing light in the wavelength range of 300 nm to 1200 nm to be incident on the optical filters 1a and 1b at an incident angle of 60° may satisfy the following requirements (v-b) and (vi-b).
(i-b) A maximum reflectance R⁵₃₀₀₋₄₅₀ in the wavelength range of 300 nm to 450 nm is 20% or less.
(ii-b) A maximum reflectance R⁵₃₀₀₋₆₀₀ in the wavelength range of 300 nm to 600 nm is 25% or less.
(iii-b) A maximum reflectance R⁴⁰₃₀₀₋₄₅₀ in the wavelength range of 300 nm to 450 nm is 20% or less.
(iv-b) A maximum reflectance R⁴⁰₃₀₀₋₆₀₀ of the wavelength range of 300 nm to 600 nm is 25% or less.
(v-b) A maximum reflectance R⁶⁰₃₀₀₋₄₅₀ of the wavelength range of 300 nm to 450 nm is 30% or less.
(vi-b) A maximum reflectance R⁶⁰₃₀₀₋₆₀₀ of the wavelength range of 300 nm to 600 nm is 35% or less.

Satisfying the above requirements (i-b) to (vi-b) is very advantageous, for example, in preventing ghosting, flare, and noise that occur when reflected light reflected on a surface of the optical filter 1a or 1b repeatedly reflects or refracts, for example, inside, at an edge, or on a lens surface of a camera module or a housing to reach an image sensing device. This is an advantage of using a light-absorbing type as a filter that cuts off (blocks) ultraviolet. The maximum reflectance R⁵₃₀₀₋₄₅₀ is desirably 15% or less. The maximum reflectance R⁴⁰₃₀₀₋₄₅₀ is desirably 15% or less. The maximum reflectance R⁶⁰₃₀₀₋₄₅₀ is desirably 20% or less. The maximum reflectance R⁵₃₀₀₋₆₀₀ is desirably 20% or less. The maximum reflectance R⁴⁰₃₀₀₋₆₀₀ is desirably 20% or less. The maximum reflectance R⁶⁰₃₀₀₋₆₀₀ is desirably 25% or less.

The optical filters 1a and 1b each may satisfy the following requirements (i-c), (ii-c), (iii-c), (iv-c), and (v-c). The symbol λ³⁰_{UV} [nm] in (i-c) represents a wavelength that lies in the wavelength range of 350 nm to 500 nm and at which the transmittance is 50% in a transmission spectrum obtained by allowing light in the wavelength range of 300 nm to 1200 nm to be incident on the optical filter at an incident angle of 30°. The symbol λ⁴⁰_{UV} [nm] in (ii-c) represents a wavelength that lies in the wavelength range of 350 nm to 500 nm and at which the transmittance is 50% in a transmission spectrum obtained by allowing light in the wavelength range of 300 nm to 1200 nm to be incident on the optical filter at an incident angle of 40°. The symbol λ⁵⁰_{UV} [nm] in (iii-c) represents a wavelength that lies in the wavelength range of 350 nm to 500 nm and at which the transmittance is 50% in a transmission spectrum obtained by allowing light in the wavelength range of 300 nm to 1200 nm to be incident on the optical filter at an incident angle of 50°. The symbol λ⁶⁰_{UV} [nm] in (iv-c) represents a wavelength that lies in the wavelength range of 350 nm to 500 nm and at which the transmittance is 50% in a transmission spectrum obtained by allowing light in the wavelength range of 300 nm to 1200 nm to be incident on the optical filter at an incident angle of 60°. The symbol λ⁷⁰_{UV} [nm] in (v-c) represents a wavelength that lies in the wavelength range of 350 nm to 500 nm and at which the transmittance is 50% in a transmission spectrum obtained by allowing light in the wavelength range of 300 nm to 1200 nm to be incident on the optical filter at an incident angle of 70°.
(i-c) |λ³⁰_{UV}−λ_{UV}|≤2.4 nm
(ii-c) |λ⁴⁰_{UV}−λ_{UV}|≤3 nm
(iii-c) |λ⁵⁰_{UV}−λ_{UV}|≤5 nm
(iv-c) |λ⁶⁰_{UV}−λ_{UV}|≤9 nm
(v-c) |Δ⁷⁰_{UV}−λ_{UV}|≤18 nm

An ultraviolet cut-off filter of full absorption type can have an advantage in that a transmission spectrum thereof has a small angle dependence. The UV cut-off wavelength of an ultraviolet cut-off filter that cuts off ultraviolet by means of its reflecting film formed of a dielectric multilayer film tends to shift toward the short wavelength side when light is obliquely incident. Because of this, ultraviolet that should be cut off may be detected by a sensor depending on the incident angle. On the other hand, in the case of the optical filters 1a and 1b satisfying the above requirements (i-c) to (v-c), the UV cut-off wavelength varies less at oblique incidence and is less likely to shift toward the short wavelength side. Therefore, the optical filters 1a and 1b are likely to achieve, in addition to the function of reducing ghosting and flare, such good color reproduction that uneven in-plane coloring happens less, and are likely to produce high-quality images.

As to (i-c), |λ³⁰_{UV}−λ_{UV}| desirably satisfies |λ³⁰_{UV}−λ_{UV}|≤1.6 nm, more desirably |λ³⁰_{UV}−λ_{UV}|≤1.2 nm. As to (ii-c), |λ⁴⁰_{UV}−λ_{UV}| desirably satisfies |λ⁴⁰_{UV}−λ_{UV}|≤2.5 nm, more desirably |λ⁴⁰_{UV}−λ_{UV}|≤2 nm. As to (iii-c), |λ⁵⁰_{UV}−λ_{UV}| is desirably |λ⁵⁰_{UV}−λ_{UV}|≤3.5 nm, more desirably |λ⁵⁰_{UV}−λ_{UV}|≤3 nm. As to (iv-c), |λ⁶⁰_{UV}−λ_{UV}| is desirably |λ⁶⁰_{UV}−λ_{UV}|≤6 nm, more desirably |λ⁶⁰_{UV}−λ_{UV}|≤5 nm. As to (v-c), |λ⁷⁰_{UV}−λ_{UV}| is desirably |λ⁷⁰_{UV}−λ_{UV}|≤12 nm, more desirably |λ⁷⁰_{UV}−λ_{UV}|≤9 nm.

The optical filter 1a consists of, for example, the light-absorbing film 10 alone. In this case, the optical filter 1a can be used, for example, independently of an image sensing device or an optical component. The optical filter 1a may be joined to an image sensing device or an optical component. Alternatively, the optical filter 1a may be formed by applying the above light-absorbing composition to an image sensing device or an optical component and curing the light-absorbing composition. As described above, the optical filter 1a may be manufactured by forming the light-absorbing film 10 on an image sensing device or an optical component.

The optical filter 1a can be produced, for example, by peeling the light-absorbing film 10 formed on a substrate off the substrate. In this case, the material of the substrate may be a glass, a resin, or a metal. A surface of the substrate may have been subjected to a surface treatment such as coating with a fluorine-containing compound. As described above, the optical filter 1a may be manufactured by forming the light-absorbing film 10 on a substrate and peeling the light-absorbing film 10 off the substrate.

As shown in FIG. 2A, the optical filter 1b includes the light-absorbing film 10 and a transparent dielectric substrate 20. The light-absorbing film 10 is provided parallel with one principal surface of the transparent dielectric substrate 20. The light-absorbing film 10 may be in contact, for example, with the one principal surface of the transparent dielectric substrate 20. In this case, for example, the light-absorbing film 10 can be formed by applying the above light-absorbing composition to the one principal surface of the transparent dielectric substrate 20 and curing the light-absorbing composition.

The type of the transparent dielectric substrate 20 is not limited to a particular type. The transparent dielectric substrate 20 may have the absorption ability in the infrared region. The transparent dielectric substrate 20 may have an average spectral transmittance of 90% or more, for example, in the wavelength range of 350 nm to 900 nm. The material of the transparent dielectric substrate 20 is not limited to a particular material and is, for example, a certain type of glass or resin. When the material of the transparent dielectric substrate 20 is a glass, the transparent dielectric substrate 20 can be, for example, a transparent glass substrate made of a silicate glass such as soda-lime glass or borosilicate glass or a substrate made of a phosphate or fluorophosphate glass containing a coloring component such as Cu or Co. The phosphate or fluorophosphate glass containing the coloring component is, for example, an infrared-absorbing glass, and has light-absorption properties in itself. In the case where the light-absorbing film 10 is used along with the transparent dielectric substrate 20 being an infrared-absorbing glass, an optical filter having desired optical properties can be produced by adjusting the light-absorption properties and transmission spectra of the light-absorbing film 10 and the transparent dielectric substrate 20 and the flexibility in designing optical filters is high.

When the material of the transparent dielectric substrate 20 is a resin, the resin is, for example, a cyclic olefin resin such as a norbornene resin, a polyarylate resin, an acrylic resin, a modified acrylic resin, a polyimide resin, a polyetherimide resin, a polysulfone resin, a polyethersulfone resin, a polycarbonate resin, or a silicone resin.

The optical filters 1a and 1b each may be modified to further include another functional film such as an infrared-absorbing film, an infrared-reflecting film, or an antireflection film. Such a functional film can be laid on the light-absorbing film 10 or the transparent dielectric substrate 20. For example, in the case where the optical filter includes an antireflection film, the transmittance in a given wavelength range (e.g., the visible region) can be increased. The antireflection film may be configured as a layer of a low-refractive-index material such as MgF₂ or SiO₂, may be configured as a laminate composed of a layer of such a low-refractive-index material and a layer of a high-refractive-index material such as TiO₂, or may be configured as a dielectric multilayer film. The antireflection film can be formed by a method including a physical reaction such as vacuum deposition or sputtering or a method including a chemical reaction such as CVD or a sol-gel process.

The optical filter may be configured, for example, in such a manner that the light-absorbing film 10 is disposed between two glass plates. In this case, the light-absorbing film 10 is a so-called intermediate film. This improves the stiffness and the mechanical strength of the optical filter. This also makes a principal surface of the optical filter hard, which is advantageous, for example, in preventing scratches. This advantage is important, in particular, in the case where a relatively flexible resin is included as a binder or a matrix in the light-absorbing film 10.

An optical filter having better optical properties can be provided by laying an antireflection film on a surface of a light-absorbing film or an optical filter obtained by curing the light-absorbing composition. For example, as shown in FIG. 2B, an optical filter 1c including the light-absorbing film 10 and an antireflection film 30 can be provided. When light is incident on the optical filter including the antireflection film at a given incident angle, light reflected by the optical filter is reduced to almost zero. This is very advantageous, for example, for an imaging apparatus equipped with the optical filter including the antireflection film in preventing ghosting, flare, and noise occurring due to multiple scattering of reflected light, for example, inside the imaging apparatus or a camera module.

The material of the antireflection film is not limited to a particular material. The method for forming the antireflection film is not limited to a particular method. The method for forming the antireflection film may be a gas-phase method or a liquid-phase method. For example, the method for forming the antireflection film may be deposition. The method for forming the antireflection film may be a sol-gel process using a reactive material including silicon. This sol-gel process is a liquid-phase method suitable for formation of the antireflection film.

The antireflection film is in the form of a single-layer film made of a single material or a multilayer film made of two or more different materials. The materials of the film and the layers in the multilayer film are not limited to particular materials. Examples of the materials include inorganic compounds such as SiO₂, TiO₂, Ta₂O₃, MgF₂, Al₂O₃, CaF₂, ZrO₂, CeO₂, and ZnS. For example, in the case where the antireflection film or a layer included in the antireflection film includes SiO₂, the film or the layer may be formed by what is called a sol-gel process using an alkoxysilane compound as a starting material. By the sol-gel process, the alkoxysilane compound undergoes hydrolysis and then polycondensation under the presence of water and a catalyst to give a dense and hard film including SiO₂. The sol-gel process has an advantage in that the SiO₂-including film or layer can be formed thereby without need for high temperatures.

The starting material used to form the antireflection film by the sol-gel process is not limited to a particular material, and a functional group in the starting material is not limited to a particular functional group, either. The starting material desirably includes an alkyl-containing trifunctional silane and a tetrafunctional silane, such as methyltriethoxysilane (MTES) and tetraethoxysilane (TEOS). The tetrafunctional silane is indispensable in formation of a film or layer having a firm and dense structure. However, it is difficult to control the reactivity and adjust the porosity of the film or layer by the tetrafunctional silane alone. Moreover, the use of the tetrafunctional silane alone tends to cause a crack in the film or layer. The starting material including the trifunctional silane as well as the tetrafunctional silane improves the flexibility of a silica structure, makes it easy to adjust the porosity of the film or layer, and makes it likely to reduce cracking in the film or layer. The ease of adjustment of the porosity of the film or layer is desired from the viewpoint of adjustment of a refractive index of the antireflection film. An organic functional group in the trifunctional silane is basically not limited to a particular functional group. The trifunctional silane desirably includes a methyl group as the organic functional group especially to form a homogeneous liquid and a homogeneous coating film in combination with the tetrafunctional silane.

In the starting material, a ratio between an amount of the alkyl-containing trifunctional silane and an amount of the tetrafunctional silane is not limited to a particular value. In the starting material, the following relation is desirably satisfied on a mass basis: the amount of the alkyl-containing trifunctional silane:the amount of the tetrafunctional silane=5:1 to 1:3. In this case, cracking in the antireflection film is likely to be reduced and a firm structure is likely to be formed owing to the tetrafunctional silane. The starting material may include a component other than the components involved in the sol-gel process. For example, the starting material may include fine particles and fillers for refractive index adjustment. In this case, the fine particles and the fillers may be hollow and/or may be made of a high-refractive-index material. The starting material may include a component that decomposes at low temperatures. In this case, it is easy to adjust the refractive index of the antireflection film. In the sol-gel process, a temperature at which the coating film is sintered is not limited to a particular temperature. The temperature is, for example, in the range of 60 °C to 250 °C, desirably in the range of 70 °C to 230 °C, more desirably in the range of 80 °C to 200 °C.

In the case where the antireflection film is a single-layer film, the material of the single-layer film desirably has a low refractive index. The reflectance tends to be smallest at n₁=√n₀, where n₁ is a refractive index of the material of the antireflection film. The symbol n₀ represents a refractive index of a substrate on which the antireflection film is formed. For example, in the case where the antireflection film includes hollow particles made of a metal oxide such as SiO₂ or TiO₂ or an organic material such as PMMA, a substantial refractive index of the particle can be decreased and the antireflection film is likely to have a low refractive index because the inside of the hollow particle is occupied by air, which has a refractive index of approximately 1. A permittivity and a refractive index of a mixture composed of a plurality of phases can be determined by effective medium approximation using the Bruggeman equation. When the refractive index required of the antireflection film is not very low, the antireflection film may include solid particles made of any of the above materials. Including such solid particles in the antireflection film is advantageous for the antireflection film required to have mechanical strength such as scratch resistance. The film may be formed by the sol-gel process with the above hollow particles or solid particles included in the starting material. In particular, in the case of using hollow particles or solid particles made of SiO₂, an affinity between the SiO₂ in the film formed by the sol-gel process and the hollow particles or the solid particles is high enough to reduce aggregation of the hollow particles or the solid particles, and thus, for example, bleed out can be reduced.

The antireflection film may have a multilayer structure including the SiO₂-including layer formed by the sol-gel process and a layer formed by, for example, vacuum deposition, the sol-gel process, or another method. For example, the multilayered antireflection film formed of two or more materials having different refractive indices is likely to ensure a relatively wide wavelength band where a reflection prevention effect is achieved and decrease the minimum reflectance of the optical filter. In the case where the SiO₂-including layer formed by the sol-gel process is combined with another layer to form the multilayer structure of the antireflection film, the other layer may be, for example, a SiO₂-including layer including the hollow particles and formed by the sol-gel process, a layer made of a material, such as TiO₂ or Ta₂O₃, having a relatively high refractive index, or a layer made of another material such as MgF₂.

### EXAMPLES

The present invention will be described in more detail by examples. The present invention is not limited to the examples given below. First, methods for evaluating optical filters according to Examples and Comparative Example will be described.

### <Measurement of Transmission and Reflection Spectra>

Transmission spectra and reflection spectra were measured for the optical filters at given incident angles using an ultraviolet-visible-near-infrared spectrophotometer (manufactured by JASCO Corporation; product name: V-670).

### <Measurement of Thickness>

The thickness of a light-absorbing film of each optical filter was measured using a laser displacement meter (manufactured by Keyence Corporation; product name: LK-H008) by measuring a distance to a surface of the optical filter and then subtracting the thickness of a transparent glass substrate of the optical filter from the distance.

### <Scratch Resistance Test>

Kuraclean wiper LF-8G manufactured by KURARAY CO., LTD. was impregnated with ethanol, propylene glycol monomethyl ether (PGME), or propylene glycol monomethyl ether acetate (PGMEA) to give an alcohol-moistened wiper. A surface of each of light-absorbing films obtained in Examples and Comparative Example was rubbed with the alcohol-moistened wiper pressed against the light-absorbing film at a pressure of 40 to 60 g/cm² in such a manner that the alcohol-moistened wiper was moved back and forth 10 times over a distance of approximately 3 cm. After that, the condition of the surface of the light-absorbing film was visually examined. The light-absorbing film was rated as “A” when there was no significant change. The light-absorbing film was rated as “B” when a scratch was found on its surface. The light-absorbing film was rated as “C” when peeling of the light-absorbing film was confirmed. Table 8 shows the results.

### <Ultraviolet-Absorbing Compound>

The following ultraviolet-absorbing compounds were used to produce the optical filters according to Examples and Comparative Example.

TABLE 1

| Ultraviolet-absorbing | |
|---|---|
| compound | |
| (Ultraviolet absorbent) | Name of compound |
| (1-1) | 2,2′,4,4′-Tetrahydroxybenzophenone |
| (1-2) | 2,2′-Dihydroxy-4,4′- |
| | dimethoxybenzophenone |

Structural formulae of the ultraviolet-absorbing compounds (1-1) and (1-2) are respectively represented by the following formulae (C) and (D).

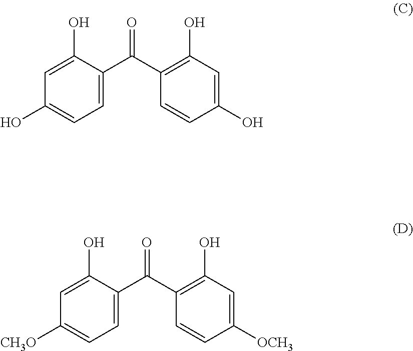

### <Compound Including Metal Component>

The following materials including a metal component were used to produce the optical filters according to Examples and Comparative Examples.

TABLE 2

| Material | | | Solvent and | Metal |
|---|---|---|---|---|
| including | Included | | solvent | component |
| metal | metal | | content | content |
| component | component | Compound | [mass %] | [mass %] |
| (2-1) | Al | Aluminum tris(ethylacetate) | — | 6.5 |
| (2-2) | Al | Aluminum bis ethyl acetoacetate | 2-Propanol | 5.3 |
| | | mono acetylacetonate | 24.0 | |
| (2-3) | Ti | Titanium diisopropoxy | 2-Propanol | 9.9 |
| | | bis(acetylacetonate) | 25.0 | |
| (2-4) | Ti | Titanium tetraacetylacetonate | 2-Propanol | 7.0 |
| | | | 35.0 | |
| (2-5) | Zr | Zirconium tetraacetylacetonate | — | 19.0 |

### Example 1

An amount of 5.0 g of the ultraviolet absorbent (1-1) shown in Table 1, 80.0 g of cyclohexanone as a solvent, and 8.0 g of polyvinyl butyral (PVB) S-LEC KS-10 (molecular weight: 1.7×10⁴; degree of acetalization: 74 mol %; hydroxy group content: 25 mol %) manufactured by Sekisui Chemical Co., Ltd. were mixed, followed by stirring for 30 minutes. Subsequently, 0.308 g of the material (2-1) including a metal component and shown in Table 2 was added to the resulting mixture, followed by stirring for 30 minutes. Furthermore, 4.0 g of tolylene diisocyanate (TDI) was added to the resulting mixture, followed by stirring for 30 seconds to give a light-absorbing composition according to Example 1. Tables 3 and 4 show the amounts of the components, the mass ratios between given components, and the molar ratio between given components in the light-absorbing composition according to Example 1. Incidentally, the mass ratios and the molar ratio between the components of the light-absorbing composition according to Example 1 were determined on the assumption that the content of the metal component in the material (2-1) was 6.5 mass % as described in Table 2.

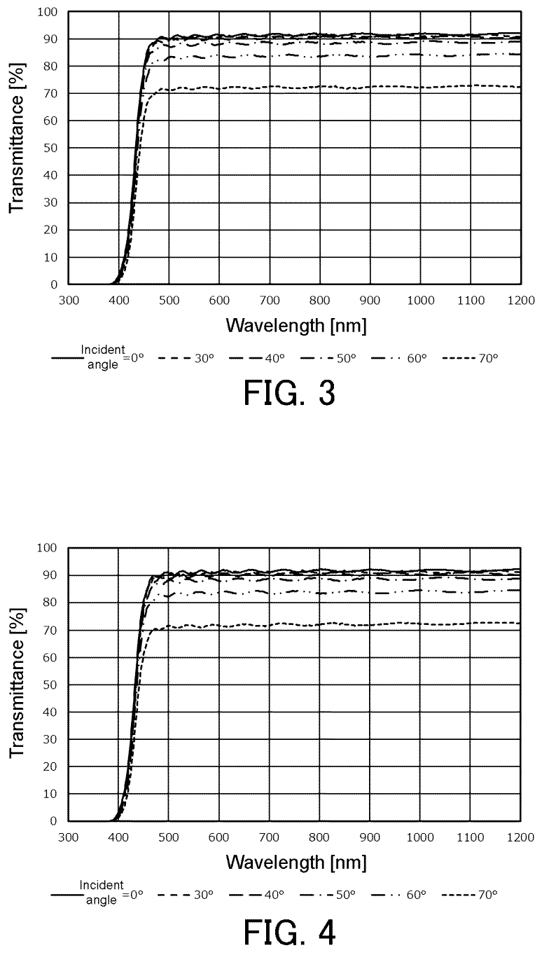

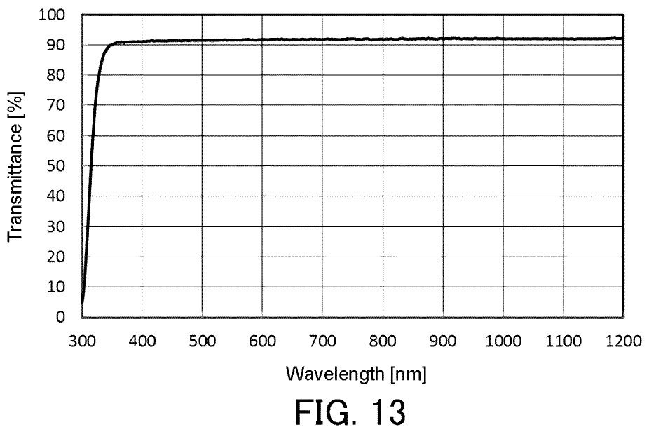

The light-absorbing composition according to Example 1 was applied by spin coating at a rotation speed of 500 rotations per minute (rpm) to one principal surface of a transparent glass substrate (manufactured by SCHOTT AG; product name: D263 T eco) made of borosilicate glass having dimensions of 76 mm×76 mm×0.21 mm to form a coating film. After sufficiently dried at room temperature, the coating film was put in an oven and subjected to thermal treatment at 140 °C for one hour and then at 160 °C for two hours to cause a crosslinking reaction between the PVB and the TDI and give a light-absorbing film according to Example 1. An optical filter including the light-absorbing film according to Example 1 was produced in this manner. FIG. 3 shows transmission spectra of the optical filter according to Example 1. FIG. 8 shows reflection spectra of the optical filter according to Example 1. Tables 5, 6, and 7 show the thickness of the light-absorbing film of the optical filter according to Example 1 and values relating to optical properties thereof. Table 8 shows the results of the scratch resistance test of the light-absorbing film according to Example 1. FIG. 13 shows a transmission spectrum of the transparent glass substrate at an incident angle of 0°.

### Examples 2 to 4

Light-absorbing compositions according to Examples 2 to 4 were prepared in the same manner as in Example 1, except that the added amount of the isocyanate and/or the type of PVB were changed as shown in Table 3. Light-absorbing films and optical filters according to Examples 2 to 4 were produced in the same manner as in Example 1, except that the light-absorbing compositions according to Examples 2 to 4 were used instead of the light-absorbing composition according to Example 1. The PVB used in Example 4 was S-LEC KS-1 (molecular weight: 2.7×10⁴; degree of acetalization: 74 mol %; hydroxy group content: 25 mol %) manufactured by Sekisui Chemical Co., Ltd. Tables 5, 6, and 7 show values relating to optical properties and obtainable from transmission spectra and reflection spectra of the optical filters according to Examples 2 to 4. From these results, it is understood that good optical properties can be obtained even when the ratio of the mass of the isocyanate to the mass of the PVB in the light-absorbing composition varies in the range of 0.18 to 1.50. Table 8 shows the results of the scratch resistance test of the light-absorbing films according to Examples 2 to 4.

### Examples 5 and 6

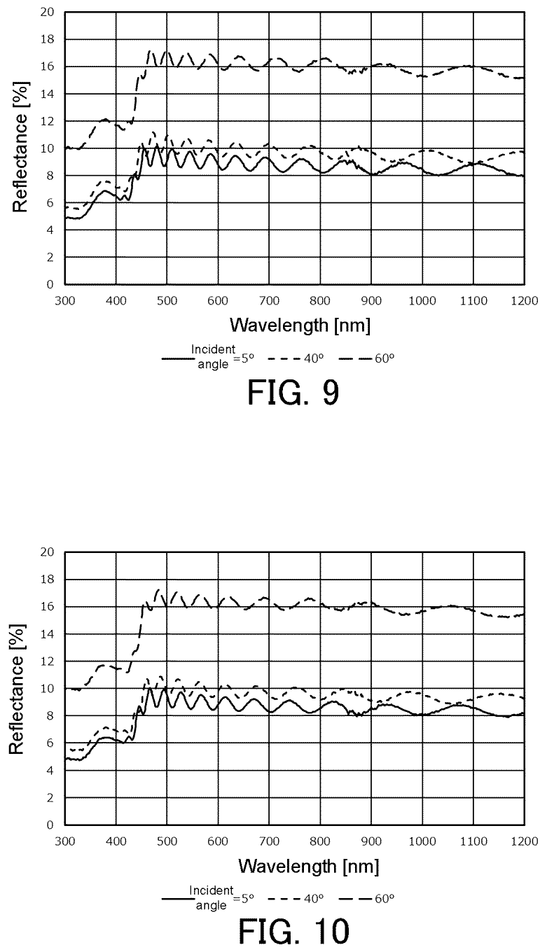

Light-absorbing compositions according to Examples 5 and 6 were prepared in the same manner as in Example 1, except that the type of PVB and the type and the added amount of isocyanate were changed as shown in Table 3. Light-absorbing films and optical filters according to Examples 5 and 6 were produced in the same manner as in Example 1, except that the light-absorbing compositions according to Examples 5 and 6 were used instead of the light-absorbing composition according to Example 1. The PVB used in Example 5 was S-LEC BX-L (molecular weight: 1.8×10⁴; degree of acetalization: 67 mol %; hydroxy group content: 32 mol %) manufactured by Sekisui Chemical Co., Ltd., and the PVB used in Example 6 was S-LEC BX-1 (molecular weight: 10×10⁴; degree of acetalization: 72 mol %; hydroxy group content: 27 mol %) manufactured by Sekisui Chemical Co., Ltd. The isocyanate used in Example 5 was diphenylmethane diisocyanate (MDI), and the isocyanate used in Example 6 was hexamethylene diisocyanate (HDI). FIG. 4 shows transmission spectra of the optical filter according to Example 5. FIG. 9 shows reflection spectra of the optical filter according to Example 5. Tables 5, 6, and 7 show values relating to optical properties of the optical filter according to Examples 5 and 6. It is understood from Examples 5 and 6 that good optical properties can be obtained even when MDI or HDI is used instead of TDI. Table 8 shows the results of the scratch resistance test of the light-absorbing films according to Examples 5 and 6.

### Examples 7 to 14

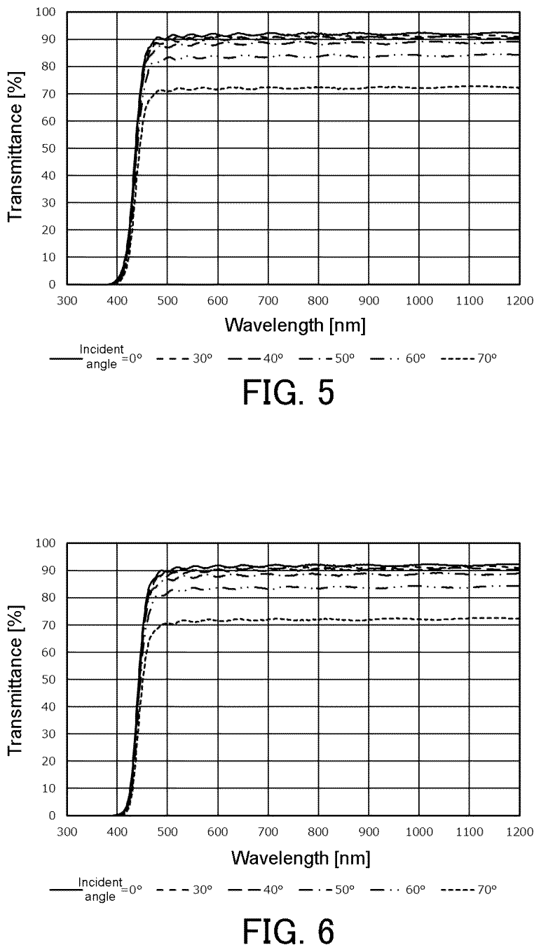

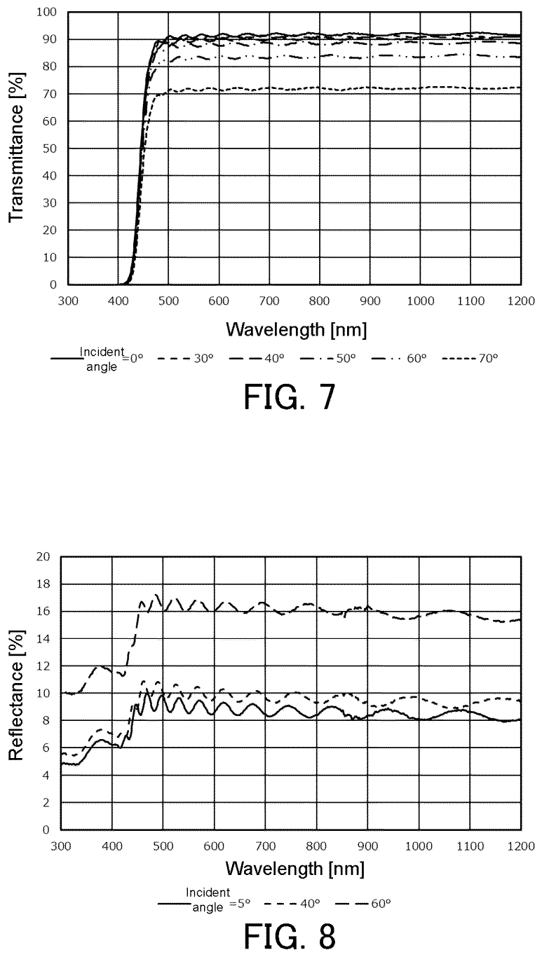

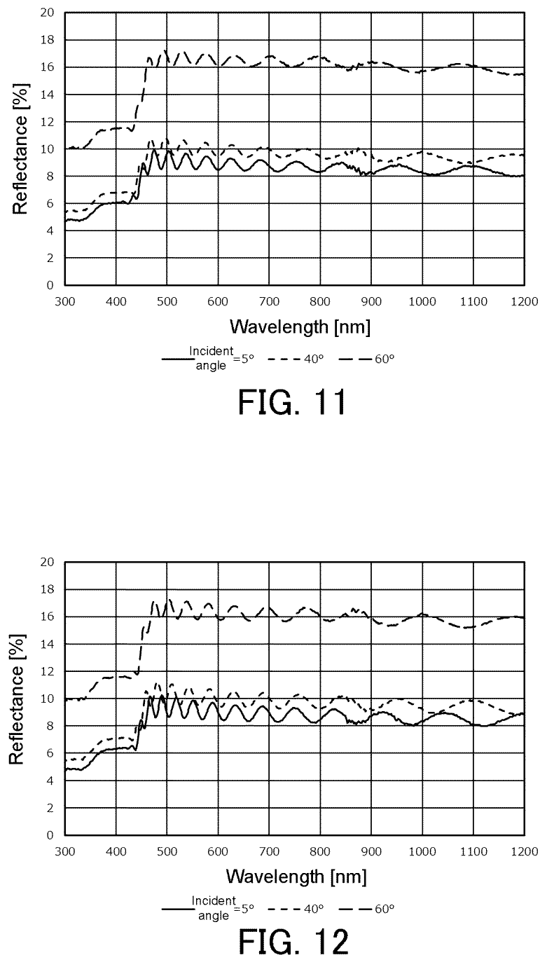

Light-absorbing composition according to Examples 7 to 14 were prepared in the same manner as in Example 1, except that the types and the added amounts of the ultraviolet-absorbing compound, the material including a metal component, the PVB, and the isocyanate were changed as shown in Table 3. Light-absorbing films and optical filters according to Examples 7 to 14 were produced in the same manner as in Example 1, except that the light-absorbing compositions according to Examples 7 to 14 were used instead of the light-absorbing composition according to Example 1. The PVB used in Example 7 was S-LEC BX-1 manufactured by Sekisui Chemical Co., Ltd. The PVB used in Example 8 was S-LEC KS-1 manufactured by Sekisui Chemical Co., Ltd. The PVB used in Example 12 was S-LEC BL-S(molecular weight: 2.3×10⁴; degree of acetalization: 72 mol %; hydroxy group content: 23 mol %) manufactured by Sekisui Chemical Co., Ltd. The PVB used in Example 13 was S-LEC BL-1 (molecular weight: 1.9×10⁴; degree of acetalization: 63 mol %; hydroxy group content: 36 mol %) manufactured by Sekisui Chemical Co., Ltd. In Examples 9, 10, 11, and 14, S-LEC KS-10 manufactured by Sekisui Chemical Co., Ltd. was used as the PVB. FIGS. 5, 6, and 7 show transmission spectra of the optical filters according to Examples 7, 9, and 11, respectively. FIGS. 10, 11, and 12 shows reflection spectra of the optical filters according to Examples 7, 9, and 11, respectively. Furthermore, Tables 5, 6, and 7 show values relating to optical properties of the optical filters according to Examples 7 to 14. Table 8 shows the results of the scratch resistance test of the light-absorbing films according to Examples 7 to 14.

### Comparative Example 1

A light-absorbing composition according to Comparative Example 1 was prepared in the same manner as in Example 1, except that no isocyanate was added. A light-absorbing film and an optical filter according to Comparative Example 1 was produced in the same manner as in Example 1, except that the light-absorbing composition according to Comparative Example 1 was used instead of the light-absorbing composition according to Example 1. Tables 5, 6, and 7 show values relating to optical properties of the optical filter according to Comparative Example 1. Table 8 shows the results of the scratch resistance test of the light-absorbing film according to Comparative Example 1.

The optical filters according to Examples and Comparative Example 1 had good optical properties in terms of reproducing the visual sensitivity of humans. Meanwhile, comparison between Examples and Comparative Example indicates that good solvent resistance and good scratch resistance tend to be achieved by the light-absorbing composition including both the PVB and the isocyanate. It is indicated that good solvent resistance and good scratch resistance tend to be achieved particularly when the ratio of the mass of the isocyanate to the mass of the PVB is 0.15 or more in the light-absorbing composition. It is thought that the ratio of the mass of the isocyanate to the mass of the PVB is desirably 0.15 or more, more desirably 0.18 or more in terms of good solvent resistance and good scratch resistance. It is thought that the upper limit of the ratio of the mass of the isocyanate to the mass of the PVB is not limited to a particular value; however, it is thought that the ratio is desirably 1.50 or less in terms of reducing curing of the light-absorbing composition just after application of the light-absorbing composition due to a large amount of the isocyanate and thereby facilitating formation of a light-absorbing film having a flat and uniform thickness. It is indicated that in terms of good optical properties, good solvent resistance, and good scratch resistance, the ratio of the mass of the isocyanate to the mass of the ultraviolet-absorbing compound is desirably 0.3 or more and that the ratio is more desirably in the range of 0.3 to 2.4.

TABLE 3

| | Ultraviolet- | | Material | | | | | | | |
|---|---|---|---|---|---|---|---|---|---|---|
| | absorbing | | including metal | | | | | | | |
| | compound | | component | | PVB | | | | | |
| | | Added | | Added | | Added | | | | |
| | | amount | | amount | | amount | Isocyanate [g] | | | Solvent |
| | Type | [g] | Type | [g] | Type | [g] | TDI | MDI | HDI | [g] |
| Example 1 | (1-1) | 5.0 | (2-1) | 0.308 | KS-10 | 8.0 | 4.0 | 0 | 0 | 80.0 |
| Example 2 | (1-1) | 5.0 | (2-1) | 0.308 | KS-10 | 8.0 | 2.0 | 0 | 0 | 80.0 |
| Example 3 | (1-1) | 5.0 | (2-1) | 0.308 | KS-10 | 8.0 | 1.5 | 0 | 0 | 80.0 |
| Example 4 | (1-1) | 5.0 | (2-1) | 0.308 | KS-1 | 8.0 | 12.0 | 0 | 0 | 80.0 |
| Example 5 | (1-1) | 5.0 | (2-1) | 0.308 | BX-L | 8.0 | 0 | 6.0 | 0 | 80.0 |
| Example 6 | (1-1) | 5.0 | (2-1) | 0.308 | BX-1 | 8.0 | 0 | 0 | 4.0 | 80.0 |
| Example 7 | (1-1) | 5.0 | (2-1) | 0.431 | BX-1 | 8.0 | 4.0 | 0 | 0 | 80.0 |
| Example 8 | (1-2) | 5.0 | (2-1) | 0.554 | KS-1 | 8.0 | 4.0 | 0 | 0 | 80.0 |
| Example 9 | (1-2) | 5.0 | (2-2) | 0.906 | KS-10 | 8.0 | 4.0 | 0 | 0 | 80.0 |
| Example 10 | (1-1) | 5.0 | (2-3) | 0.545 | KS-10 | 8.0 | 4.0 | 0 | 0 | 80.0 |
| Example 11 | (1-1) | 5.0 | (2-4) | 0.857 | KS-10 | 8.0 | 4.0 | 0 | 0 | 80.0 |
| Example 12 | (1-1) | 5.0 | (2-1) | 1.477 | BL-S | 8.0 | 2.0 | 0 | 0 | 80.0 |
| Example 13 | (1-1) | 5.0 | (2-1) | 1.569 | BL-1 | 8.0 | 2.0 | 0 | 0 | 80.0 |
| Example 14 | (1-1) | 5.0 | (2-1) | 1.754 | KS-10 | 8.0 | 2.0 | 0 | 0 | 80.0 |
| Comparative | (1-1) | 5.0 | (2-1) | 0.308 | KS-10 | 8.0 | 0.0 | 0 | 0 | 80.0 |
| Example 1 | | | | | | | | | | |

TABLE 4

| | Mass | Molar | | Mass | Ultraviolet- | |
|---|---|---|---|---|---|---|
| | ratio of | ratio of | | ratio of | absorbing | Metal |
| | ultraviolet- | ultraviolet- | Mass | isocyanate | compound | component |
| | absorbing | absorbing | ratio of | to | content in light- | content in light- |
| | compound | compound | isocyanate | ultraviolet- | absorbing | absorbing |
| | to metal | to metal | to curable | absorbing | composition | composition |
| | component | component | resin | compound | [mass %] | [mass %] |
| Example 1 | 249.75 | 27.37 | 0.500 | 0.800 | 5.36 | 0.021 |
| Example 2 | 249.75 | 27.37 | 0.250 | 0.400 | 5.36 | 0.021 |
| Example 3 | 249.75 | 27.37 | 0.188 | 0.300 | 5.36 | 0.021 |
| Example 4 | 249.75 | 27.37 | 1.500 | 2.400 | 5.36 | 0.021 |
| Example 5 | 249.75 | 27.37 | 0.750 | 1.200 | 5.36 | 0.021 |
| Example 6 | 249.75 | 27.37 | 0.500 | 0.800 | 5.36 | 0.021 |
| Example 7 | 178.48 | 19.56 | 0.500 | 0.800 | 5.85 | 0.033 |
| Example 8 | 138.85 | 13.66 | 0.500 | 0.800 | 5.34 | 0.038 |
| Example 9 | 104.13 | 10.24 | 0.500 | 0.800 | 5.32 | 0.051 |
| Example 10 | 92.67 | 18.02 | 0.500 | 0.800 | 5.35 | 0.058 |
| Example 11 | 83.35 | 16.20 | 0.500 | 0.800 | 5.33 | 0.064 |
| Example 12 | 52.08 | 5.71 | 0.250 | 0.400 | 5.29 | 0.102 |
| Example 13 | 49.03 | 5.37 | 0.250 | 0.400 | 5.29 | 0.108 |
| Example 14 | 43.86 | 4.81 | 0.250 | 0.400 | 5.28 | 0.120 |
| Comparative | 249.75 | 27.37 | 0.000 | 0.000 | 5.36 | 0.021 |
| Example 1 | | | | | | |

TABLE 5

| | Thickness | | | | | | |
|---|---|---|---|---|---|---|---|
| | of light- | | | | | | |
| | absorbing | T^{M}₃₀₀₋₃₈₀ | T₄₀₀ | T₄₁₀ | λ_{UV} | T^{m}₄₈₀₋₆₀₀ | |
| | film [μm] | [%] | [%] | [%] | [nm] | [%] | T⁰_{UV+}/T⁰_{UV-} |
| Example 1 | 2.3 | 0.06 | 3.5 | 9.3 | 433 | 89.8 | 2.54 |
| Example 2 | 2.3 | 0.05 | 3.6 | 9.5 | 433 | 89.8 | 2.51 |
| Example 3 | 2.3 | 0.05 | 3.5 | 9.6 | 433 | 89.8 | 2.51 |
| Example 4 | 2.4 | 0.04 | 3.2 | 9.1 | 433 | 89.4 | 2.56 |
| Example 5 | 2.3 | 0.04 | 3.3 | 9.3 | 433 | 89.3 | 2.54 |
| Example 6 | 2.3 | 0.04 | 3.3 | 9.3 | 433 | 89.3 | 2.54 |
| Example 7 | 2.4 | 0.05 | 1.9 | 5.4 | 436 | 90.0 | 2.74 |
| Example 8 | 2.4 | 0.05 | 1.2 | 3.3 | 439 | 88.2 | 3.37 |
| Example 9 | 2.8 | 0.03 | 0.3 | 1.1 | 443 | 88.5 | 5.27 |
| Example 10 | 2.8 | 0.03 | 0.2 | 0.6 | 444 | 88.0 | 6.58 |
| Example 11 | 2.9 | 0.02 | 0.1 | 0.3 | 445 | 88.9 | 8.15 |
| Example 12 | 2.2 | 0.04 | 0.0 | 0.1 | 448 | 87.3 | 12.50 |
| Example 13 | 2.1 | 0.05 | 0.0 | 0.1 | 448 | 88.7 | 13.39 |
| Example 14 | 2.1 | 0.04 | 0.0 | 0.1 | 450 | 86.6 | 17.82 |
| Comparative | 2.3 | 0.05 | 3.4 | 9.4 | 433 | 89.8 | 2.53 |
| Example 1 | | | | | | | |

TABLE 6

| | \|λ³⁰_{UV} − | \|λ⁴⁰_{UV} − | \|λ⁵⁰_{UV} − | \|λ⁶⁰_{UV} − | \|λ⁷⁰_{UV} − |
|---|---|---|---|---|---|
| | λ_{UV}\| | λ_{UV}\| | λ_{UV}\| | λ_{UV}\| | λ_{UV}\| |
| | [nm] | [nm] | [nm] | [nm] | [nm] |
| Example 1 | 1 | 2 | 3 | 4 | 8 |
| Example 5 | 1 | 2 | 3 | 4 | 8 |
| Example 7 | 1 | 2 | 3 | 4 | 8 |
| Example 9 | 1 | 2 | 2 | 4 | 8 |
| Example 11 | 1 | 1 | 2 | 4 | 7 |

TABLE 7

| | R⁵₃₀₀₋₄₅₀ | R⁴⁰₃₀₀₋₄₅₀ | R⁶⁰₃₀₀₋₄₅₀ | R⁵₃₀₀₋₆₀₀ | R⁴⁰₃₀₀₋₆₀₀ | R⁶⁰₃₀₀₋₆₀₀ |
|---|---|---|---|---|---|---|
| | [%] | [%] | [%] | [%] | [%] | [%] |
| Example 1 | 9.2 | 9.1 | 15.4 | 10.0 | 10.9 | 17.2 |
| Example 5 | 8.9 | 10.4 | 15.5 | 10.1 | 11.2 | 17.2 |
| Example 7 | 8.7 | 8.8 | 15.2 | 10.0 | 10.9 | 17.2 |
| Example 9 | 8.6 | 8.9 | 13.4 | 9.9 | 10.8 | 17.2 |
| Example 11 | 8.4 | 8.0 | 14.2 | 10.2 | 11.2 | 17.3 |

TABLE 8

| | Solvent | | |
|---|---|---|---|
| | Ethanol | PGME | PGMEA |
| Example 1 | A | A | A |
| Example 2 | A | A | A |
| Example 3 | A | A | A |
| Example 4 | A | A | A |
| Example 5 | A | A | A |
| Example 6 | A | A | A |
| Example 7 | A | A | A |
| Example 8 | A | A | A |
| Example 9 | A | A | A |
| Example 10 | A | A | A |
| Example 11 | A | A | A |
| Example 12 | A | A | A |
| Example 13 | A | A | A |
| Example 14 | A | A | A |
| Comparative | C | C | C |
| Example 1 | | | |

1. A light-absorbing composition comprising:
an ultraviolet-absorbing compound having a hydroxy group and a carbonyl group in a molecule;
a metal component;
polyvinyl butyral; and
an isocyanate, wherein
at least a portion of the metal component is bonded to an organic oxy group.

2. The light-absorbing composition according to claim 1, wherein a content of the metal component in the light-absorbing composition is 0.005% to 2% on a mass basis.

3. The light-absorbing composition according to claim 1, wherein a content of the ultraviolet-absorbing compound in the light-absorbing composition is 0.1% to 20% on a mass basis.

4. The light-absorbing composition according to claim 1, wherein a ratio of a mass of the ultraviolet-absorbing compound to a mass of the metal component is 5 to 300.

5. The light-absorbing composition according to claim 1, wherein a ratio of a mass of the isocyanate to a mass of the polyvinyl butyral is 0.05 to 3.0.

6. The light-absorbing composition according to claim 1, wherein a ratio of a mass of the isocyanate to a mass of the ultraviolet-absorbing compound is 0.1 to 3.0.

7. The light-absorbing composition according to claim 1, wherein the hydroxy group and the carbonyl group are disposed with one to three atoms in between.

8. The light-absorbing composition according to claim 1, wherein the ultraviolet-absorbing compound includes a benzophenone-based compound represented by the following formula (A1): 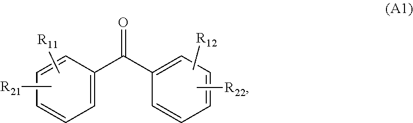
where at least one of R₁₁, R₁₂, R₂₁, and R₂₂ is a hydroxy group; and in the case where the R₁₁, the R₁₂, the R₂₁, or the R₂₂ is a functional group other than a hydroxy group, a plurality of the R_{11S}, a plurality of the R_{12S}, a plurality of the R_{21S}, or a plurality of the R_{22S} are optionally present and at least one of the R₁₁, the R₁₂, the R₂₁, and the R₂₂ is optionally absent.

9. The light-absorbing composition according to claim 1, wherein the ultraviolet-absorbing compound includes a benzophenone-based compound represented by the following formula (A2): 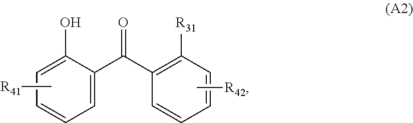
where R₃₁ is a hydrogen atom, a hydroxy group, a carboxyl group, an aldehyde group, a halogen atom, a halogen-containing group, an alkyl group having 1 to 12 carbon atoms, or an alkoxy group having 1 to 12 carbon atoms; R₄₁ and R₄₂ are each optionally a hydroxy group, a carboxyl group, an aldehyde group, a halogen-containing group, an alkyl group having 1 to 12 carbon atoms, an aryl group having 6 to 12 carbon atoms, or an alkoxy group having 1 to 12 carbon atoms, or the R₄₁ and the R₄₂ are optionally absent; and a plurality of the R₄₁s are optionally present, and a plurality of the R₄₂s are optionally present.

10. The light-absorbing composition according to claim 1, wherein the metal component includes at least one selected from the group consisting of Li, Na, Mg, Ca, Sr, Ba, Ge, Sn, Pb, Al, Ga, In, Tl, Zn, Cd, Cu, Ag, Au, Ni, Pd, Pt, Co, Rh, Ir, Fe, Mn, Cr, Mo, W, V, Nb, Ta, Ti, and Zr.

11. A method for manufacturing the light-absorbing composition according to claim 1, the method comprising adding and mixing an ultraviolet-absorbing compound having a hydroxy group and a carbonyl group in a molecule, a compound including a metal component, polyvinyl butyral, and an isocyanate in an organic solvent.

12. Alight-absorbing film comprising:
an ultraviolet-absorbing compound having a hydroxy group and a carbonyl group in a molecule;
a metal component; and
a resin including a urethane bond, wherein
at least a portion of the metal component is bonded to an organic oxy group.

13. The light-absorbing film according to claim 12, wherein a ratio of a mass of the ultraviolet-absorbing compound to a mass of the metal component is 5 to 300.

14. The light-absorbing film according to claim 12, wherein
the urethane bond is located between a first portion derived from polyvinyl butyral and a second portion derived from an isocyanate, and
a ratio of a sum of a mass of an isocyanate and a mass of the second portion to a sum of a mass of polyvinyl butyral and a mass of the first portion is 0.05 to 3.0.

15. The light-absorbing film according to claim 12, wherein
the urethane bond is located between a first portion derived from polyvinyl butyral and a second portion derived from an isocyanate, and
a ratio of a sum of a mass of an isocyanate and a mass of the second portion to a mass of the ultraviolet-absorbing compound is 0.1 to 3.0.

16. The light-absorbing film according to claim 12, wherein the hydroxy group and the carbonyl group are disposed with one to three atoms in between.

17. The light-absorbing film according to claim 12, wherein a transmittance T₄₀₀ at a wavelength of 400 nm is 5% or less in a transmission spectrum at an incident angle of 0°.

18. The light-absorbing film according to claim 12, wherein the ultraviolet-absorbing compound includes a benzophenone-based compound represented by the following formula (A1): 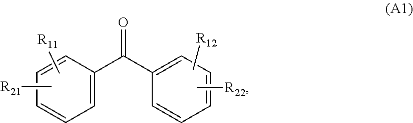
where at least one of R₁₁, R₁₂, R₂₁, and R₂₂ is a hydroxy group; and in the case where the R₁₁, the R₁₂, the R₂₁, or the R₂₂ is a functional group other than a hydroxy group, a plurality of the Riis, a plurality of the R_{12S}, a plurality of the R_{21S}, or a plurality of the R_{22S} are optionally present and at least one of the R₁₁, the R₁₂, the R₂₁, and the R₂₂ is optionally absent.

19. The light-absorbing film according to claim 12, wherein the ultraviolet-absorbing compound includes a benzophenone-based compound represented by the following formula (A2): 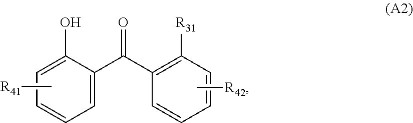
where R₃₁ is a hydrogen atom, a hydroxy group, a carboxyl group, an aldehyde group, a halogen atom, a halogen-containing group, an alkyl group having 1 to 12 carbon atoms, or an alkoxy group having 1 to 12 carbon atoms; R₄₁ and R₄₂ are each optionally a hydroxy group, a carboxyl group, an aldehyde group, a halogen-containing group, an alkyl group having 1 to 12 carbon atoms, an aryl group having 6 to 12 carbon atoms, or an alkoxy group having 1 to 12 carbon atoms, or the R₄₁ and the R₄₂ are optionally absent; and a plurality of the R_{41S} are optionally present, and a plurality of the R_{42S} are optionally present.

20. The light-absorbing film according to claim 12, wherein
a transmission spectrum obtained by allowing light in a wavelength range of 300 nm to 1200 nm to be incident on the light-absorbing film at an incident angle of 0° satisfies the following requirements (i-a), (ii-a), (iii-a), (iv-a), (v-a), and (vi-a):
(i-a) a maximum transmittance in a wavelength range of 300 nm to 380 nm is 3% or less;
(ii-a) a transmittance at a wavelength of 400 nm is 5% or less;
(iii-a) a transmittance at a wavelength of 410 nm is 10% or less;
(iv-a) a wavelength λ_{UV} that lies in a wavelength range of 350 nm to 500 nm and at which a transmittance is 50% is in a range of 405 nm to 490 nm;
(v-a) a minimum transmittance in a wavelength range of 480 nm to 600 nm is 85% or more; and
(vi-a) a ratio of a transmittance at a wavelength of (λ_{UV}+10) nm to a transmittance at a wavelength of (λ_{UV}−10) nm is 1.8 or more.

21. An optical filter comprising the light-absorbing film according to claim 12.

22. A method for manufacturing an optical filter comprising the light-absorbing film according to claim 12, the method comprising either (i) or (ii) below:
(i) forming the light-absorbing film on an image sensing device or an optical component; or
(ii) forming the light-absorbing film on a substrate, and peeling the light-absorbing film off the substrate.
